(19) United States
(12) Patent Application Publication
(10) Pub. No.: US 2013/0260507 A1
(43) Pub. Date: Oct. 3, 2013

(54) Method for Forming a Fibrous Layer

(71) Applicants: Jean-Paul Garandet, Le Bourget Du Lac (FR); Armand Bettinelli, Coublevie (FR); Béatrice Drevet, Grenoble (FR); Etienne Pihan, Chambery (FR); Philippe Thony, Entre-deux-Guiers (FR)

(72) Inventors: Jean-Paul Garandet, Le Bourget Du Lac (FR); Armand Bettinelli, Coublevie (FR); Béatrice Drevet, Grenoble (FR); Etienne Pihan, Chambery (FR); Philippe Thony, Entre-deux-Guiers (FR)

(73) Assignee: COMMISSARIAT A L'ENERGIE ATOMIQUE ET AUX ENERGIES ALTERNATIVES, Paris (FR)

(21) Appl. No.: 13/989,365

(22) PCT Filed: Nov. 21, 2011
(86) PCT No.: PCT/IB2011/055212

§ 371 Date: Jun. 14, 2013

(30) Foreign Application Priority Data
Nov. 24, 2010 (FR) 10 59661

(51) Int. Cl. H01L 31/0236

(52) U.S. Cl. CPC H01L 31/02363
USPC 438/71

(57) ABSTRACT

The present invention relates to a method for forming, on the surface of one of the sides of a silicon substrate, a fibrous layer having a mean lattice pitch of no more than 2 μm, without requiring soaking.

The invention also relates to devices, in particular photovoltaic cells, comprising a silicon substrate produced by means of such a method.

The present invention relates to a process for forming, at the surface of one of the faces of a silicon substrate, a fibrous layer having a mean lattice pitch of less than or equal to 2 μm. This process is particularly advantageous within the context of producing photovoltaic cells, for forming on their back face a layer of fibrous structure capable of ensuring the diffraction of infrared photons.

Photovoltaic cells are for the most part manufactured from monocrystalline or polycrystalline silicon. Generally, these standard industrial cells based on silicon have a back face electric field, also referred to as BSF (Back Surface Field) obtained by an aluminum-silicon (Al—Si) eutectic alloy formed by annealing an aluminum layer deposited by screenprinting on a silicon substrate. This annealing of the back face contacts is carried out according to standard technology in a tunnel furnace.

More specifically, such an annealing requires bringing the assembly to a temperature of the order of 800° C. for a few seconds, in order to form a liquid alloy between the silicon and the aluminum. On cooling, the first stages of solidification of this liquid alloy result in the deposition of a single-phase Al-saturated Si layer of a few microns, which forms the back field (BSF) of the photovoltaic cells. Once the eutectic temperature of the Al—Si system (577° C.) is reached, the solidification becomes two-phase and results in a structure formed of silicon lamellae in an aluminum matrix. However, such a structure, which generally has inter-lamellar spacings of the order of 10 to 20 μm, unfortunately has significant topological disorder.

Consequently, the structures present on the back face of a photovoltaic cell produced from this standard process do not enable a diffraction of the infrared photons not absorbed by the silicon of the cell, i.e. photons with a wavelength of less than 1.1 μm corresponding to the silicon bandgap, and which would therefore be capable of generating charge carriers.

In order to improve the efficiency of photovoltaic cells, it would therefore be desirable to be able to produce a back face structure of the cells, enabling the diffraction of the infrared photons not absorbed by the silicon, and thus improving their “collection” within the cell.

The problem of absorption of the photons is faced with a particular intensity in the case of methods based on the recrystallization of thin layers deposited by vapor phase vacuum technologies (for example, by the techniques CVD (ii) and PVD (iii)). Regarding layers that are often very thin (generally less than 20 μm, often of the order of 1 μm), the use of means that make it possible to lengthen the optical path of the photons on the front and/or rear face of the cells is necessary for obtaining advantageous energy conversion efficiencies for industrial applications.

In order to do this, microelectronics techniques make it possible to produce, by etching of organized reliefs, lattices having good uniformity and a mean pitch suitable for the diffraction of infrared photons.

However, these techniques have the drawback of being particularly expensive. In particular, they are not compatible with the standard technology of annealing in a tunnel furnace, customarily used in the production of photovoltaic cells, and hence make it necessary to carry out major adaptations of the process for manufacturing photovoltaic cells.

Also, it is well known, especially in the field of metallurgy, to be able to transform the lamellar form of the Al—Si eutectic into a fibrous form, by addition, to the molten alloy, of a modifier such as sodium (Na) or strontium (Sr). Various theories have been developed to try to explain the obtaining of such a fibrous structure (iv).

However, as specified above, under the standard conditions of annealing in a tunnel furnace, more particularly for a solidification of the molten alloy at rates of the order of 5 to 25 μm/s, corresponding to cooling rates of the order of 10 to 50° C./s which are characteristic of tunnel furnaces, the spacings of the fibrous eutectic structure obtained are greater than 2 μm, and are not therefore suitable for a diffraction of the infrared photons.

The techniques of rapid quenching may furthermore make it possible to obtain structures with a reduced lattice pitch. Unfortunately, besides their difficulty in processing on solid samples, the quenching techniques induce high stress levels. The structures obtained at the end of quenching operations prove, in addition, to be brittle and not very easy to handle and consequently do not make it possible to continue the subsequent steps essential for the production of the photovoltaic cells.

Consequently, there remains a need to be able to produce a structure having a mean lattice pitch that is significantly reduced, and in particular advantageously less than or equal to 2 μm, capable of ensuring the diffraction of the infrared photons not absorbed by the silicon, by a process that is furthermore compatible with the standard technology for producing photovoltaic cells, in particular that is compatible with an annealing of the contacts in a tunnel furnace.

The present invention specifically aims to provide a process that satisfies the aforementioned requirements.

In particular, the present invention relates, according to a first one of its aspects, to a process for forming, at the surface of one face of a silicon substrate, a fibrous layer (22) having a mean lattice pitch of less than or equal to 2 μm, comprising at least the steps consisting in:

(1) providing a silicon substrate, one of the faces of which is at least partly covered with a mixture comprising at least aluminum and at least one modifier element chosen from the elements from columns IA and IIA of the periodic table, and

(2) exposing at least the coated face of said substrate from step (1) to a heat treatment suitable for (a) the formation of a molten alloy comprising silicon, aluminum and said modifier elements and for (b) the consecutive solidification of said molten alloy under conditions suitable for the formation of at least one layer (22) having a two-phase eutectic structure consisting of silicon-based fibers in an aluminum-based matrix, with a mean lattice pitch of less than or equal to 2 μm,

characterized in that said mixture from step (1) also comprises from 20% to 60% by weight, relative to its total weight, of one or more additional elements chosen from gallium, indium, tin, zinc and mixtures thereof.

Against all expectations, the inventors have discovered that it is thus possible to attain a fibrous layer having a mean lattice pitch of less than or equal to 2 μm, by using a liquid alloy comprising, besides the silicon, aluminum and one or more modifier elements, a large amount of one or more metallic elements chosen from gallium (Ga), indium (In), tin (Sn) and zinc (Zn).

Such a process is all the more surprising since the standard processes for producing photovoltaic cells usually seek to avoid any prejudicial contamination of the silicon by metallic elements, known for acting as recombinant centers for minority charge carriers (v).

Thus, the process according to the invention is advantageous on several counts.

Firstly, it makes it possible to attain a layer of fibrous structure having a mean lattice pitch of less than or equal to 2 μm, particularly suitable for the diffraction of infrared photons, in particular having a wavelength of less than 1.1 μm corresponding to the bandgap of the silicon. Such a fibrous structure at the back of a cell thus enables the “collection” of infrared photons by diffraction, and the improvement of the efficiency of the photovoltaic cell.

Moreover, step (2) of the process according to the invention may be carried out with the industrial techniques usually employed for producing photovoltaic cells, more specifically the standard technology of firing in a tunnel furnace. Thus, advantageously, the process of the invention does not require significant modifications of the standard process for producing photovoltaic cells. More particularly, as expanded upon subsequently, it is possible according to the process of the invention to form, in a single step, the back surface field (BSF) and the diffracting fibrous layer.

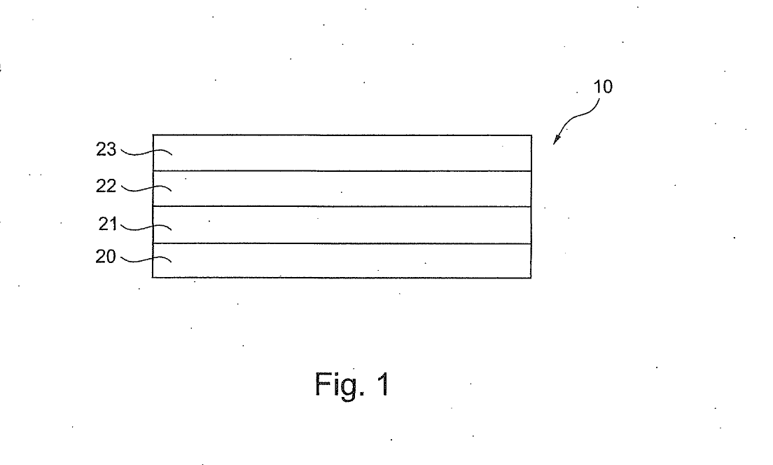

Other features, advantages and modes of application of the process according to the invention will emerge more clearly on reading the following description, given by way of illustration and nonlimitingly with reference to the appended FIG. 1.

More specifically, FIG. 1 represents a schematic cross section of a modified silicon substrate (10) obtained at the end of step (2) of the process of the invention.

It should be noted that, for reasons of clarity, the various layers visible in FIG. 1 are not drawn to scale, the actual dimensions of the various parts not being respected.

According to another of its aspects, the present invention relates to a device, in particular a photovoltaic cell, comprising a modified silicon substrate obtained according to the process described previously.

The aforementioned groups IA and IIA refer to the numberings used (Roman numerals from I to VIII according to Newlands, and letters A and B according to Moseley), well known to a person skilled in the art, denoting the elements in the periodic table of the elements, also referred to as “Mendeleev's table”.

In the remainder of the text, the expressions “between . . . and . . . ”, “ranging from . . . to . . . ” and “varying from . . . to . . . ” are equivalent and are understood to mean that the limits are included, unless otherwise mentioned.

Step (1)

As specified previously, step (1) of the process of the invention consists in providing a silicon substrate, one of the faces of which is at least partly covered with the mixture considered according to the invention.

Silicon Substrate

Within the context of the present invention, the term “substrate” refers to a base structure, to the face of which the mixture considered according to the invention is applied.

The base silicon substrate used in step (1) of the process of the invention may be of various natures. In particular, as expanded upon subsequently, it may be chosen with regard to the method of producing the photovoltaic cell.

The silicon substrate used in the process of the invention must be crystalline and have a structure made of grains with a size at least equal to 1 mm, preferably to 1 cm or more.

The silicon substrate used in the process according to the invention may be doped or undoped. Thus, the silicon used in the process according to the invention may be doped, in particular with a p-type dopant such as, for example, boron, aluminum, indium and gallium or by an n-type dopant such as, for example, phosphorus, antimony and arsenic.

The silicon substrate may, where appropriate, be juxtaposed, on the face opposite that coated with the mixture according to the invention, to other layers of materials.

The substrate may, where appropriate, undergo, prior to its use in the process of the invention, one or more transformations dedicated for example to giving it particular properties.

According to a first embodiment variant, the silicon substrate used in step (1) of the process of the invention may be a p-type silicon wafer, comprising in particular at least one p-n junction on the face opposite that coated with the mixture according to the invention, and optionally having been subjected beforehand to one or more antireflection treatment(s).

Such a silicon wafer may be produced according to conventional techniques that fall within the abilities of a person skilled in the art.

Its thickness may, for example, vary from 100 to 300 μm, in particular from 150 to 200 μm.

Within the context of this first variant, the substrate modified at the end of step (2) of the process according to the invention may then form, completely, as is, the back face of the photovoltaic cell already (partly) produced.

According to a second embodiment variant, the silicon substrate suitable for the treatment according to the invention may be a “low-cost” substrate of metallurgical silicon type, purified by segregation prior to its use in the process of the invention.

The expression “silicon substrate of metallurgical silicon type” is understood to mean silicon substrates containing high concentrations of impurities, in particular metallic impurities, of the order of 1 to 100 ppm by weight. This silicon, which may be monocrystalline silicon or polycrystalline silicon, that is to say silicon where the grains have a size of 1 mm² to several cm² and where the growth is columnar, generally contains metallic impurities such as Fe, Cr, Cu, etc., at concentrations much higher than crystalline silicon of electronic quality. Regarding the presence of impurities, this silicon is not very expensive and is particularly advantageous for being converted to a substrate having a high added value.

Such a silicon substrate may have a thickness ranging from 200 to 700 μm, in particular ranging from 300 to 500 μm.

According to one particular embodiment, at the end of step (2) of the process of the invention, the modified substrate may be used, as described subsequently, via one or more subsequent steps, as epitaxial substrate suitable for producing a cell by recrystallization of a thin layer of silicon.

The choice of a suitable silicon substrate falls within the abilities of a person skilled in the art, who will select the nature of the base silicon substrate to be used in the process of the invention, depending on the technique for producing the corresponding photovoltaic cell.

Mixture

As specified previously, the mixture considered in the process of the invention comprises at least:
aluminum;
one or more modifier element(s) chosen from the elements from columns IA and IIA of the periodic table, in particular strontium, sodium and the mixture thereof; and
one or more additional element(s) chosen from gallium, indium, tin, zinc and mixtures thereof.

According to another particular embodiment, the aluminum is present in the mixture from step (1) of the process of the invention in a content ranging from 40% to 80% by weight, preferably from 55% to 65% by weight, relative to the total weight of said mixture.

According to one particular embodiment, the modifier element(s) is (are) present in the mixture from step (1) in a content ranging from 0.01% to 0.1%, preferably from 0.02% to 0.06% by weight, relative to the total weight of said mixture.

As specified previously, such elements are known for their ability to modify the structure of the Al—Si eutectic. During its solidification, the silicon of the Al—Si eutectic grows normally in lamellar form, also referred to as “acicular form”. If it is modified by addition of a modifier element, it then grows in a fibrous form.

According to one essential feature of the invention, the mixture considered according to the invention comprises from 20% to 60% by weight of said additional element(s).

Preferably, the additional element(s) is (are) present in said mixture from step (1) in a content ranging from 35% to 45% by weight, preferably around 40% by weight, relative to the total weight of said mixture.

According to one particular embodiment, the additional element is zinc or tin.

According to one particular embodiment of the invention, the mixture of the various metallic elements may be in powder form.

Advantageously, the powder mixture has a particle size D50 expressed by volume ranging from 2 to 10 μm.

The particle size may be measured, for example, by laser particle size analysis according to a technique known to a person skilled in the art.

In one embodiment variant, the mixture in powder form, considered according to the invention, is formed by mixing the various metallic elements, each being in the form of a powder.

In another embodiment variant, a mother alloy comprising the various elements that are incorporated into the composition of the mixture of the invention is produced, then consecutively reduced to powder.

By way of example, the mixture of the invention may be produced by mixing a powder obtained by milling a mother alloy consisting of aluminum and 5% by weight of modifier element(s), with a powder obtained by mixing an aluminum powder and the additional element(s) in the form of powder(s).

Advantageously, the mixture considered according to the invention comprises, besides the mixture of the various powders, at least one binder. Such a mixture forms a screenprinting paste, which can easily be spread over the silicon base substrate.

The binder makes it possible in particular to ensure the dispersion and the cohesion of the mixture of the powders. It is generally a resin dissolved in a solvent, chosen from cellulose resins and acrylic resins. Mention may be made, by way of examples, of ethyl cellulose dissolved in a solvent such as terpineol or n-butyl methacrylate dissolved in a glycol ether.

When the mixture uses one or more binder(s), the silicon substrate coated on one of its faces with the mixture must be subjected to a drying step in order to evaporate the solvent, and then to a binder removal step, for the purposes of eliminating the binder(s) prior to step (2).

A person skilled in the art is able to carry out known techniques for binder removal, preferably by thermal decomposition, in an oven for example.

According to yet another embodiment, the mixture may comprise, in addition, glass frits. These glass frits generally consist of a mixture of SiO₂, B₂O₃, ZnO, PbO and Bi₂O₃. They advantageously make it possible to pierce the insulating layers, to facilitate the densification of the metallic particles, to create an electrical contact and to create anchorage on the substrate.

The production of the mixture considered according to the invention in the form of a suitable screenprinting paste falls within the abilities of a person skilled in the art, who will spread such a screenprinting paste on one of the faces of the silicon substrate, using suitable means.

Step (2)

Process for Forming the Fibrous Layer

In a second essential step of the process of the invention, the coated face of said silicon substrate from step (1) of the process according to the invention is exposed to a heat treatment suitable for:

(a) the formation of a molten alloy comprising the silicon and said modifier elements, and

(b) the consecutive solidification of said molten alloy under conditions suitable for the formation of the fibrous layer (22) according to the invention.

More particularly, the formation of the molten alloy (a) may be obtained by exposing the coated face of the substrate from step (1) to a temperature below the melting point of the silicon, in particular varying between 600° C. and 850° C., preferably between 700° C. and 750° C., for a time of the order of one minute.

At such a temperature, the metallic elements of the mixture considered according to the invention and the silicon melt in order to form a molten alloy by establishing thermodynamic equilibrium.

The adjustment of the temperature and time conditions fall within the abilities of a person skilled in the art.

In a consecutive stage (b), the molten zone is exposed to conditions that enable the solidification of the molten alloy. These conditions require, in particular, a cooling of the molten zone below the melting point.

This cooling may be gradual, with several cooling rates during one and the same cycle, from 5° C./s to 50° C./s.

During the cooling (b), the following appear successively, as represented in FIG. 1:
a single-phase layer (21) based on silicon, which grows epitaxially on the part of the silicon substrate (20) that has remained solid;
the fibrous layer (22) considered according to the invention, having a two-phase eutectic structure consisting of silicon-based fibers in an aluminum-based matrix, and
one or more layer(s) (23) of eutectic structure having at least three phases, the mean composition(s) of which is (are) close to that of said additional element(s).

Thus, step (2) of the process of the invention results in the formation of an outer layer (23) of eutectic structure having at least three phases, said outer layer (23) comprising most of said additional element(s).

Furthermore, step (2) of the process of the invention results in the formation of an intermediate layer (21) between said fibrous layer (22) and said silicon substrate (20), of single-phase structure and predominantly comprising silicon.

FIG. 1 represents the various layers of the silicon substrate (10) obtained at the end of step (2) of the process of the invention.

According to one particularly preferred embodiment, steps (a) and (b) are carried out continuously.

The heat treatment may be carried out in a heated chamber into which the silicon substrate according to the invention is introduced.

This chamber is suitable, in particular, for ensuring the exposure of the face of the substrate coated with the mixture described previously, to heating under the aforementioned conditions.

The silicon substrate and said chamber may be moved relative to one another so that any molten zone in step (a) is moved consecutively to the zone of the chamber suitable for its solidification (b) by cooling.

More particularly, it is the silicon substrate that is moved through the chamber.

Advantageously, this heat treatment may be carried out according to the standard process for annealing contacts, generally via static or dynamic lamp furnaces. This heat treatment may be carried out in air or under a non-oxidizing atmosphere such as a stream of argon, helium, etc.

As regards the cooling step, it may be carried out by natural cooling after having switched off the heating source or else by forced cooling, for example by passing a stream of air over the substrate.

Advantageously, step (2) is carried out via the introduction of the silicon substrate from step (1) into a tunnel furnace, under standard operating conditions, conventionally used for the production of photovoltaic cells, and that are well known to a person skilled in the art.

Features of the Fibrous Layer Formed According to the Invention

As specified previously, the fibrous layer (22) formed according to the process of the invention has a mean lattice pitch of less than or equal to 2 μm.

Advantageously, said fibrous layer (22) has a mean pitch ranging from 0.5 to 1.5 μm.

In particular, said fibrous layer (22) may have a thickness between 1 and 20 μm, preferably between 5 and 10 μm.

Within the meaning of the invention, the expression “silicon-based” fibers is understood to mean the fact that said fibers formed predominantly comprise silicon, in other words consist of more than 99.99% by weight of silicon.

The “aluminum-based” matrix predominantly comprises aluminum, in other words consists of 98.5% by weight of aluminum. Therefore, the maximum solubility of silicon in aluminum is around 1.5% by weight at the eutectic temperature.

As regards the other layers formed at the end of step (2) of the process of the invention, the single-phase layer (21) adjacent to the base silicon substrate (20) may, in the case when it is of p type, act, within a photovoltaic cell, as a back surface field (BSF), that is to say act as an electric field that repels the minority carriers at the back face of the cell.

The process according to the invention may advantageously be used to form, in a single step, both the back surface field of a photovoltaic cell and the desired diffracting fibrous layer.

The upper layer (23), adjacent to the fibrous layer (22) of the invention, has a three-phase structure in the case where a single additional element is used in the mixture considered according to the invention.

It has a four-phase structure, or even a structure containing more than four phases, when at least two additional elements are introduced into the mixture considered according to the invention.

This layer (23) is of no relevance for the diffraction of the infrared photons, but may have the benefit of conducting electricity which is advantageous for the contacting and the assembly into modules.

According to a first variant of producing a photovoltaic cell, the process of the invention is carried out, as mentioned previously, starting from a p-type silicon wafer, on which a p-n junction has already been produced, and optionally one or more antireflection treatment(s) have already been carried out.

The modified substrate obtained at the end of step (2) of the process according to the invention may then form, completely, as is, the back face of the photovoltaic cell. In particular, this photovoltaic cell will have, at the back face, the single-phase layer (21) forming the BSF, and the fibrous layer (22) of the invention, enabling the diffraction of the infrared photons not absorbed by the silicon.

Thus, according to another of its aspects, one subject of the present invention is a device, in particular a photovoltaic cell, formed completely or partly of a modified silicon substrate, as obtained at the end of step (2) of the process described previously.

In particular, said modified silicon substrate is obtained according to the process of the invention, starting from a p-type silicon wafer comprising at least one p-n junction on its other face, and optionally having been subjected beforehand to an antireflection treatment.

The invention also advantageously enables:
a reduction of the thermomechanical stresses and the curvature of the wafers following the contact annealing step; and
the possibility of adding to the screenprinting paste a source of boron in order to increase the doping level of the BSF.

In a second variant of producing a photovoltaic cell, the process of the invention is carried out in order to form an epitaxial substrate suitable for the recrystallization of one or more thin layers of silicon.

According to this variant, the silicon substrate from step (1) may be, as specified previously, a substrate of metallurgical silicon type, purified by segregation.

According to this variant, the process of the invention may also comprise a step (3) comprising the elimination of the eutectic layer(s) (23) having at least three phases formed at the end of step (2) and adjacent to the fibrous layer considered according to the invention, and the elimination of the aluminum matrix from the fibrous layer.

This step (3) may be carried out according to techniques known to those skilled in the art, in particular by chemical pickling of the substrate obtained at the end of step (2) of the process of the invention, in particular using orthophosphoric acid.

Such a pickling step (3) makes it possible to eliminate all of the metallic elements other than the silicon.

At the end of the pickling step (3), the substrate is in the form of a bed of nails consisting of silicon needles.

These needles may especially have a height ranging from 2 μm to 10 μm, in particular around 5 μm.

Such a substrate is suitable for depositing layers of amorphous or nanocrystalline silicon via PVD-type technology (iii) without risking blocking up the spaces between the needles.

Next, a solid-phase annealing induces a recrystallization of this amorphous or nanocrystalline silicon layer, starting from the needles in order to form the active layer of the photovoltaic cell.

The layer of fibers will also form, according to this embodiment, the back face of the final cell.

Thus, according to yet another of its aspects, one subject of the present invention is a device, formed completely or partly of a modified silicon substrate, as obtained at the end of step (3) of the process described previously.

In particular, the present invention relates to a device, especially a photovoltaic cell, characterized in that an additional layer of silicon is superimposed on said modified silicon substrate, as obtained at the end of step (3) of the process of the invention.

The invention will now be described by means of the following two examples, illustrating more particularly the two variants of implementation of the process of the invention in the production of a photovoltaic cell.

These examples are of course given by way of illustration and without limitation of the invention.

### EXAMPLES

### Example 1

### Process According to the Invention Used for Producing a Photovoltaic Cell by Annealing of Back Contact

An alloy containing 60% by weight of Al and 40% by weight of Zn is produced by mixing micron-sized powders (D₅₀ between 2 and 20 μm). Sr is added in the form of powders obtained by milling an Al-5% by weight of Sr mother alloy so that the content of Sr in the Al—Zn—Sr alloy is 500 ppm by weight. These powders are agglomerated with a binder of cellulose type (ethyl cellulose dissolved in terpineol), and optionally glass frits, in order to form a paste suitable for screenprinting.

This paste is deposited on a p-type Si wafer on which the p-n junction has already been produced and the antireflection treatments have already been carried out.

The assembly is introduced into a tunnel furnace in order to achieve a maximum temperature of 750° C., which results in a portion of the Si of the substrate dissolving in order to ensure the thermodynamic equilibrium.

The first structure deposited during the cooling is single-phase and grows epitaxially on the Si of the substrate, it acts as a back repulsive field for the application.

Then, once the temperature of the two-phase eutectic is reached, a structure consisting of silicon-based fibers, in an aluminum-based matrix, and having a mean spacing of 1.4 μm is obtained.

Formed next is a ternary eutectic structure, with a mean composition rich in Zn.

### Example 2

### Process According to the Invention Used for Forming an Epitaxial Substrate Suitable for the Recrystallization of Thin Layers for the Production of a Photovoltaic Cell

An alloy containing 60% by weight of Al and 40% by weight of Sn is produced by mixing micron-sized powders (D₅₀ between 2 and 10 μm). Sr is added in the form of powders obtained by milling an Al-5% by weight of Sr mother alloy so that the content of Sr in the Al—Sn—Sr alloy is 500 ppm by weight. These powders are agglomerated with a binder of acrylic type (n-butyl methacrylate dissolved in a glycol ether), and optionally glass frits, in order to form a paste suitable for screenprinting.

This paste is deposited on a low-cost substrate of metallurgical Si type, purified by segregation.

The assembly is introduced into a tunnel furnace in order to achieve a maximum temperature of 700° C., which results in a portion of the Si of the substrate dissolving in order to ensure the thermodynamic equilibrium.

The first structure deposited during the cooling is single-phase and grows epitaxially on the Si of the substrate.

Then, once the temperature of the two-phase eutectic is reached, a structure consisting of fibers predominantly comprising silicon, in a matrix predominantly comprising aluminum, is obtained.

Finally, when the temperature of the invariant ternary eutectic is reached, a ternary eutectic structure having a mean composition rich in Sn is formed.

The resolidified assembly is subjected to chemical pickling (for example using orthophosphoric acid) in order to keep only the Si. The substrate is in the form of a bed of nails consisting of needles of Si having a height close to 5 μm with a spacing of the order of 1.2 μm.

### REFERENCES

(i) F. Huster, 20th European Photovoltaic Solar Energy Conference and Exhibition, Barcelona, 6-10 Jun. 2005, 2DV2.49;
(ii) S. Reber, A. Hurrle, A. Eyer, G. Wilke, “Crystalline silicon thin film solar cells—recent results at Fraunhofer ISE”, Solar Energy, 77 (2004) 865-875;
(iii) M. Aoucher, G. Farhi, T. Mohammed-Brahim, J. Non-Crystalline Solids, 227-230 (1998) 958;
(iv) M. M. Makhlouf, H. V Guthy, Journal of Light Metals 1 (2001) 199-218;
(v) J. R. Davis, Jr et al., “Impurities in silicon solar cells”, IEEE transactions on Electron Devices 27 (1980) 677-687.

1.-16. (canceled)

17. A process for forming, at a surface of one face of a silicon substrate, a fibrous layer having a mean lattice pitch of less than or equal to 2 μm, comprising at least the steps of:
(1) providing a silicon substrate, one face of which is at least partly coated with a mixture comprising at least aluminum and at least one modifier element chosen from the elements from columns IA and IIA of the periodic table; and
(2) exposing at least the coated face of the substrate from step (1) to a heat treatment suitable for:
(a) formation of a molten alloy comprising silicon, aluminum and the modifier elements; and
(b) consecutive solidification of the molten alloy under conditions suitable for formation of at least one layer having a two-phase eutectic structure consisting of silicon-based fibers in an aluminum-based matrix, with a mean lattice pitch of less than or equal to 2 μm;
wherein the mixture from step (1) also comprises from 20% to 60% by weight, relative to its total weight, of at least one additional element further defined as gallium, indium, tin, zinc, or a mixture comprising two or more of these.

18. The process of claim 17, wherein the fibrous layer has a mean pitch ranging from 0.5 to 1.5 μm.

19. The process of claim 17, wherein the fibrous layer has a thickness ranging from 1 to 20 μm.

20. The process of claim 17, wherein the additional element(s) is (are) present in the mixture from step (1) in a content ranging from 35% to 45% by weight, relative to the total weight of the mixture.

21. The process of claim 17, wherein the modifier element is strontium, sodium, or a mixture thereof.

22. The process of claim 17, wherein the modifier element(s) is (are) present in the mixture from step (1) in a content ranging from 0.01% to 0.1% by weight, relative to the total weight of the mixture.

23. The process of claim 17, wherein the mixture from step (1) is in the form of a powder, having a particle size D50 expressed by volume ranging from 2 to 10 μm.

24. The process of claim 17, wherein the mixture from step (1) also comprises at least one binder.

25. The process of claim 24, wherein the binder comprises a cellulose resin or an acrylic resin.

26. The process of claim 17, wherein the mixture from step (1) also comprises glass frits.

27. The process of claim 17, wherein the molten alloy of step (2) is formed by exposing the substrate from step (1) to a temperature ranging from 600° C. to 850° C.

28. The process of claim 17, wherein the solidification step (b) of the molten alloy in step (2) is carried out at a cooling rate ranging from 5 to 50° C./s.

29. The process of claim 17, wherein step (2) results in formation of an intermediate layer between the fibrous layer and the silicon substrate, of single-phase structure comprising predominantly silicon.

30. The process of claim 17, wherein the silicon substrate is a p-type silicon wafer, comprising at least one p-n junction on its other face.

31. The process of claim 30, wherein the silicon substrate has been previously been subjected to an antireflection treatment.

32. The process of claim 17, the process also comprising a step (3) comprising elimination of eutectic layer(s) containing at least three phases formed at the end of step (2) and elimination of the aluminum matrix from the fibrous layer.

33. The process of claim 32, wherein step (3) comprises chemical pickling of the product obtained at the end of step (2).

34. The process of claim 32, wherein the silicon substrate is a metallurgical silicon that has been purified by segregation.
